(19) United States
(12) Patent Application Publication
(10) Pub. No.: US 2023/0240044 A1
(43) Pub. Date: Jul. 27, 2023

(54) IMMERSION-TYPE HEAT DISSIPATION STRUCTURE AND METHOD FOR MANUFACTURING THE SAME

(71) Applicant: AMULAIRE THERMAL TECHNOLOGY, INC., New Taipei City (TW)

(72) Inventors: CHING-MING YANG, New Taipei City (TW); CHENG-SHU PENG, New Taipei City (TW); TZE-YANG YEH, New Taipei City (TW)

(21) Appl. No.: 17/582,123

(22) Filed: Jan. 24, 2022

(51) Int. Cl. H05K 7/20; B22F 3/11; B22F 10/20

(52) U.S. Cl. CPC H05K 7/203; B22F 3/11; B22F 10/20; B33Y 80/00

(57) ABSTRACT

An immersion-type heat dissipation structure and a method for manufacturing the same are provided. The immersion-type heat dissipation structure includes a first heat dissipation member and a second heat dissipation member that has a plurality of heat dissipation columns and is disposed on the first heat dissipation member. The second heat dissipation member has a porous structure, the first heat dissipation member has a solid structure, and a thermal conductivity of the first heat dissipation member is greater than that of the second heat dissipation member. A shortest distance between two bottoms of any two adjacent ones of the heat dissipation columns is between 0.2 mm and 1.2 mm, a minimum diameter of a top surface of the heat dissipation column is between 0.2 mm and 1.2 mm, and a draft angle formed on a side surface of the heat dissipation column is between 1° and 5°.

### FIELD OF THE DISCLOSURE

The present disclosure relates to a heat dissipation structure and a method for manufacturing the same, and more particularly to an immersion-type heat dissipation structure and a method for manufacturing the same.

### BACKGROUND OF THE DISCLOSURE

An immersion cooling technology is to directly immerse heat generating elements (such as servers and disk arrays) into a non-conductive coolant, and heat generated from operation of the heat generating elements is removed through an endothermic gasification process of the coolant. Therefore, how to dissipate heat more effectively through the immersion cooling technology has long been an issue to be addressed in the industry.

### SUMMARY OF THE DISCLOSURE

In response to the above-referenced technical inadequacy, the present disclosure provides an immersion-type heat dissipation structure and a method for manufacturing the same.

In one aspect, the present disclosure provides an immersion-type heat dissipation structure, which includes a first heat dissipation member and a second heat dissipation member. The second heat dissipation member has a plurality of heat dissipation columns and is disposed on the first heat dissipation member. The second heat dissipation member and the first heat dissipation member are at least partially in contact with each other. The second heat dissipation member is a porous heat dissipation member that has a porous structure, the first heat dissipation member is a solid heat dissipation member that has a solid structure, and a thermal conductivity of the first heat dissipation member is greater than a thermal conductivity of the second heat dissipation member. A shortest distance between two bottoms of any two adjacent ones of the heat dissipation columns is between 0.2 mm and 1.2 mm, a minimum diameter of a top surface of any one of the plurality of heat dissipation columns is between 0.2 mm and 1.2 mm, and a draft angle formed on a side surface of any one of the plurality of heat dissipation columns is between 1° and 5°.

In certain embodiments, the first heat dissipation member is a solid heat dissipation member that is made of at least one solid metal, and the second heat dissipation member is a porous heat dissipation member that is formed by metal injection molding and in contact with the first heat dissipation member.

In certain embodiments, each of the plurality of heat dissipation columns is at least one of a circular column, a square column, a diamond-shaped column, and an elliptical column.

In certain embodiments, the first heat dissipation member is a solid heat dissipation member that is formed by multiple solid metals, and the second heat dissipation member is a porous heat dissipation member that is formed by metal injection molding and completely covers the first heat dissipation member.

In certain embodiments, the multiple solid metals are made of different solid metal materials, respectively.

In another aspect, the present disclosure provides an immersion-type heat dissipation structure, which includes a first heat dissipation member and a second heat dissipation member. The second heat dissipation member has a plurality of heat dissipation columns and is disposed on the first heat dissipation member. The second heat dissipation member and the first heat dissipation member are at least partially jointed to each other by a medium. The second heat dissipation member is a porous heat dissipation member that has a porous structure, the first heat dissipation member is a solid heat dissipation member that has a solid structure, and a thermal conductivity of the first heat dissipation member is greater than a thermal conductivity of the second heat dissipation member. A shortest distance between two bottoms of any two adjacent ones of the heat dissipation columns is between 0.2 mm and 1.2 mm, a minimum diameter of a top surface of any one of the plurality of heat dissipation columns is between 0.2 mm and 1.2 mm, and a draft angle formed on a side surface of any one of the plurality of heat dissipation columns is between 1° and 5°.

In certain embodiments, the medium is a copper-containing solder or a thermal interface material.

In yet another aspect, the present disclosure provides a method for manufacturing an immersion-type heat dissipation structure, which includes providing a first material; performing a process of chemical micro-etching on a surface of the first material, so that the surface of the first material is formed as a micro-etching surface; placing the chemically micro-etched first material in a metal injection mold; providing a second material; and injecting the second material into the metal injection mold by metal injection molding to form the immersion-type heat dissipation structure.

In certain embodiments, the first material is at least one solid metal, and the second material is a mixture of metal powder and an adhesive.

In certain embodiments, the method for manufacturing an immersion-type heat dissipation structure further includes performing a post processing on the immersion-type heat dissipation structure. The post processing is at least one of a process of dewaxing, a process of sintering, and a secondary processing.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1A is a schematic side view of an immersion-type heat dissipation structure according to a first embodiment of the present disclosure;

FIG. 1B is an enlarged view of part II of FIG. 1A;

FIG. 2 is a schematic side view of an immersion-type heat dissipation structure according to a second embodiment of the present disclosure;

FIG. 3 is a schematic side view of an immersion-type heat dissipation structure according to a third embodiment of the present disclosure;

FIG. 4 is a schematic side view of an immersion-type heat dissipation structure according to a fourth embodiment of the present disclosure;

FIG. 5 is a schematic side view of an immersion-type heat dissipation structure according to a fifth embodiment of the present disclosure;

FIG. 6 is a schematic side view of an immersion-type heat dissipation structure according to a sixth embodiment of the present disclosure;

FIG. 7 is a schematic side view of an immersion-type heat dissipation structure according to a seventh embodiment of the present disclosure; and

FIG. 8 is a schematic side view of an immersion-type heat dissipation structure according to an eighth embodiment of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a”, “an”, and “the” includes plural reference, and the meaning of “in” includes “in” and “on”. Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first”, “second” or “third” can be used to describe various components, signals or the like, which are for distinguishing one component/signal from another one only, and are not intended to, nor should be construed to impose any substantive limitations on the components, signals or the like.

### First Embodiment

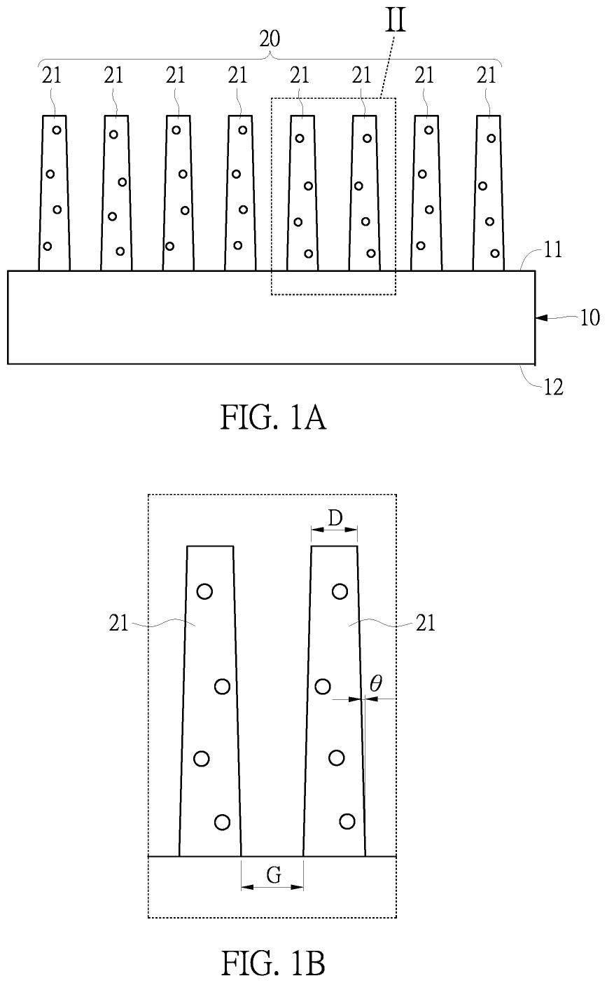

Reference is made to FIG. 1A and FIG. 1B, in which one embodiment of the present disclosure is shown. Embodiments of the present disclosure provide an immersion-type heat dissipation structure that can be used for contacting a heat generating element. As shown in FIG. 1A, the immersion-type heat dissipation structure provided by the embodiments of the present disclosure essentially includes a first heat dissipation member 10 and a second heat dissipation member 20.

In the present embodiment, the second heat dissipation member 20 has a plurality of heat dissipation columns 21, that is, the second heat dissipation member 20 is formed by the plurality of heat dissipation columns 21. A shape of each of the plurality of heat dissipation columns 21 is not limited to a circular column, but can also be a square column, a diamond-shaped column, an elliptical column, etc. Furthermore, the plurality of heat dissipation columns 21 are vertically formed on an upper surface 11 of the first heat dissipation member 10 by metal injection molding and are immersed in a two-phase coolant (such as electronic fluorinated liquid), and a lower surface 12 of the first heat dissipation member 10 can be used for contacting the heat generating element.

Further, the second heat dissipation member 20 of the present embodiment is a porous heat dissipation member having a porous structure, that is, the second heat dissipation member 20 of the present embodiment is a porous heat dissipation member having multiple porous metal heat dissipation columns. In the present embodiment, the second heat dissipation member 20 is preferably a porous heat dissipation member having multiple porous copper heat dissipation columns. It should be noted that, the porous structure is exaggeratedly enlarged in FIG. 1A and FIG. 1B for a better understanding of the present disclosure.

Furthermore, the first heat dissipation member 10 of the present embodiment is a solid heat dissipation member having a solid structure, that is, the first heat dissipation member 10 of the present embodiment is a solid heat dissipation member that is made of solid metal. In the present embodiment, the first heat dissipation member 10 is preferably a solid copper heat dissipation member. In addition, a thermal conductivity of the first heat dissipation member 10 is greater than a thermal conductivity of the second heat dissipation member 20. Therefore, in the present embodiment, the second heat dissipation member 20 is the porous heat dissipation member having the multiple porous metal heat dissipation columns, such that generation of vapor bubbles can be increased. In addition, the first heat dissipation member 10 is the solid heat dissipation member that is made of the solid metal, and the thermal conductivity of the first heat dissipation member 10 is greater than the thermal conductivity of the second heat dissipation member 20, so that thermal transmission efficiency can be increased, thereby increasing an overall immersion-type heat dissipation effect.

Further, as shown in FIG. 1B, in the present embodiment, a shortest distance G between two bottoms of any two adjacent ones of the heat dissipation columns 21 of the second dissipation heat dissipation member 20 is between 0.2 mm and 1.2 mm, a minimum diameter D of a top surface of any one of the plurality of heat dissipation columns 21 is between 0.2 mm and 1.2 mm, and a draft angle θ formed on a side surface of any one of the plurality of heat dissipation columns 21 is between 1° and 5°. An overall contact area of the second heat dissipation member 20 with the two-phase coolant is increased by reducing a diameter of the heat dissipation column 21 and a distance between any two adjacent ones of the heat dissipation columns 21, thereby further increasing the overall heat dissipation effect.

### Second Embodiment

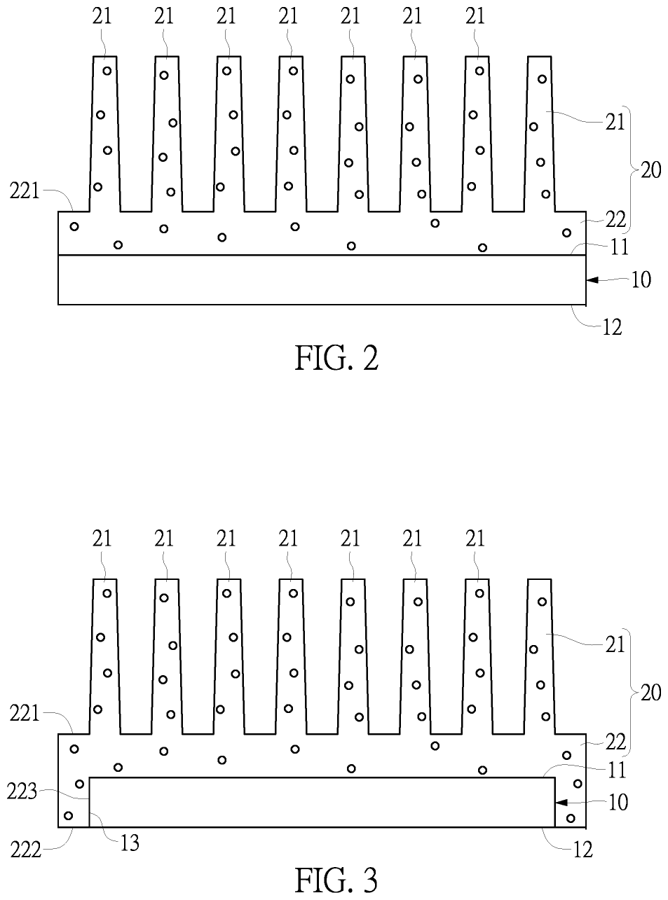

Reference is made to FIG. 2, in which a second embodiment of the present disclosure is shown. The present embodiment is substantially the same as the first embodiment, and differences therebetween are described as follows.

In the present embodiment, a second heat dissipation member 20 has a porous heat dissipation substrate 22 and the plurality heat dissipation columns 21 that are integrally formed on an upper surface 221 of the porous heat dissipation substrate 22. Further, the plurality of heat dissipation columns 21 and the porous heat dissipation substrate 22 are formed on the upper surface 11 of the first heat dissipation member 10 by metal injection molding, and are immersed in the two-phase coolant, so as to increase a contact area of the immersion-type heat dissipation structure with the two-phase coolant and to increase generation of vapor bubbles by the porous heat dissipation substrate 22. In addition, the first heat dissipation member 10 is a solid heat dissipation member that is made of solid metal, and a thermal conductivity of the first heat dissipation member 10 is greater than a thermal conductivity of the second heat dissipation member 20, so that thermal transmission efficiency can be increased, thereby increasing an overall immersion-type heat dissipation effect.

### Third Embodiment

Reference is made to FIG. 3, in which a third embodiment of the present disclosure is shown. The present embodiment is substantially the same as the first embodiment, and differences therebetween are described as follows.

In the present embodiment, the second heat dissipation member 20 has a porous heat dissipation substrate 22 and the plurality of heat dissipation columns 21 that are integrally formed on an upper surface 221 of the porous heat dissipation substrate 22. A recess 223 is formed on a lower surface 222 of the porous heat dissipation substrate 22, and is correspondingly in contact with the upper surface 11 and a side surface 13 of the first heat dissipation member 10. Further, the plurality of heat dissipation columns 21 and the porous heat dissipation substrate 22 are in contact with the upper surface 11 and the side surface 13 of the first heat dissipation member 10 by metal injection molding, and are immersed in the two-phase coolant, so as to increase a contact area of the immersion-type heat dissipation structure with the two-phase coolant and to increase generation of vapor bubbles by the porous heat dissipation substrate 22. In addition, the first heat dissipation member 10 is a solid heat dissipation member that is made of solid metal, and a thermal conductivity of the first heat dissipation member 10 is greater than a thermal conductivity of the second heat dissipation member 20, so that thermal transmission efficiency can be increased, thereby increasing an overall immersion-type heat dissipation effect.

### Fourth Embodiment

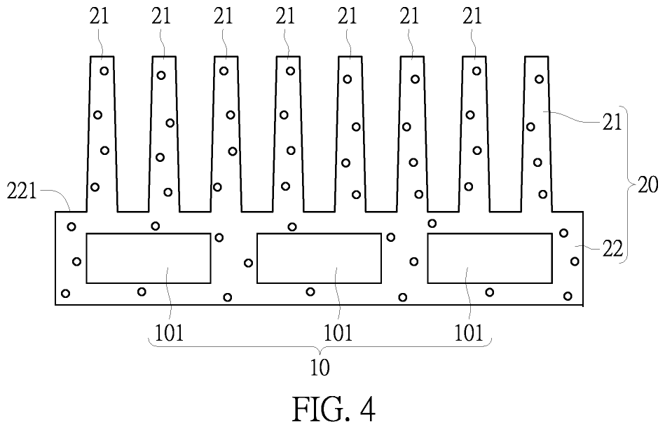

Reference is made to FIG. 4, in which a fourth embodiment of the present disclosure is shown. The present embodiment is substantially the same as the first embodiment, and differences therebetween are described as follows.

In the present embodiment, the first heat dissipation member 10 includes a plurality of solid metals 101, that is, the first heat dissipation member 10 is formed by the plurality of solid metals 101. The first heat dissipation member 10 can be formed by a plurality of solid copper metals, but the first heat dissipation member 10 can also be formed by multiple solid metals 101 that are made of different solid metal materials, respectively, such as a gold block or an aluminum block. The second heat dissipation member 20 has a porous heat dissipation substrate 22 and the plurality of heat dissipation columns 21 that are integrally formed on an upper surface 221 of the porous heat dissipation substrate 22, and the porous heat dissipation substrate 22 completely covers the first heat dissipation member that is formed by the plurality of solid metals 101. Further, the plurality of dissipation columns 21 and the porous heat dissipation substrate 22 completely covers the plurality of solid metals 101 by metal injection molding, and are immersed in the two-phase coolant, so as to increase a contact area of the immersion-type heat dissipation structure with the two-phase coolant and to increase generation of vapor bubbles by the porous heat dissipation substrate 22. In addition, a solid heat dissipation member that is formed by arranging the plurality of solid metals 101 in the porous heat dissipation substrate 22 has high thermal conductivity, so that thermal transmission efficiency can be increased, thereby increasing an overall immersion-type heat dissipation effect.

### Fifth Embodiment

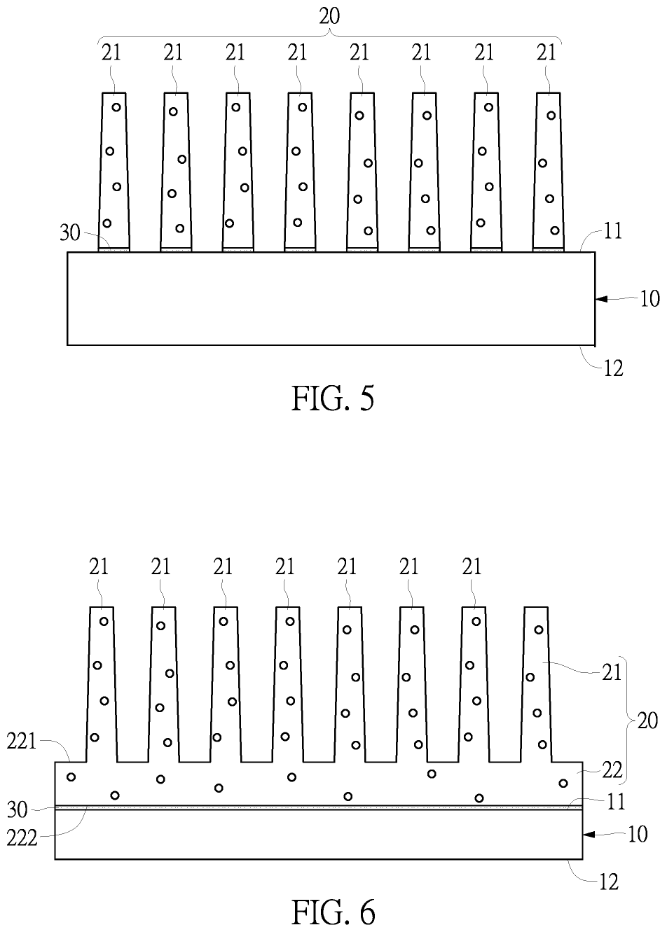

Reference is made to FIG. 5, in which a fifth embodiment of the present disclosure is shown. The present embodiment is substantially the same as the first embodiment, and differences therebetween are described as follows.

In the present embodiment, a bottom of each of a plurality of heat dissipation columns 21 of the second heat dissipation member 20 can be jointed to the upper surface 11 of the first heat dissipation member 10 by at least one medium 30. Further, the at least one medium 30 can be a copper-containing solder or a thermal interface material, such as thermally conductive silicone.

### Sixth Embodiment

Reference is made to FIG. 6, in which a sixth embodiment of the present disclosure is shown. The present embodiment is substantially the same as the second embodiment, and differences therebetween are described as follows.

In the present embodiment, a lower surface 222 of the porous heat dissipation substrate 22 of the second heat dissipation member 20 can be jointed to the upper surface 11 of the first heat dissipation member 10 by a medium 30. Further, the medium 30 can be a copper-containing solder or a thermal interface material.

### Seventh Embodiment

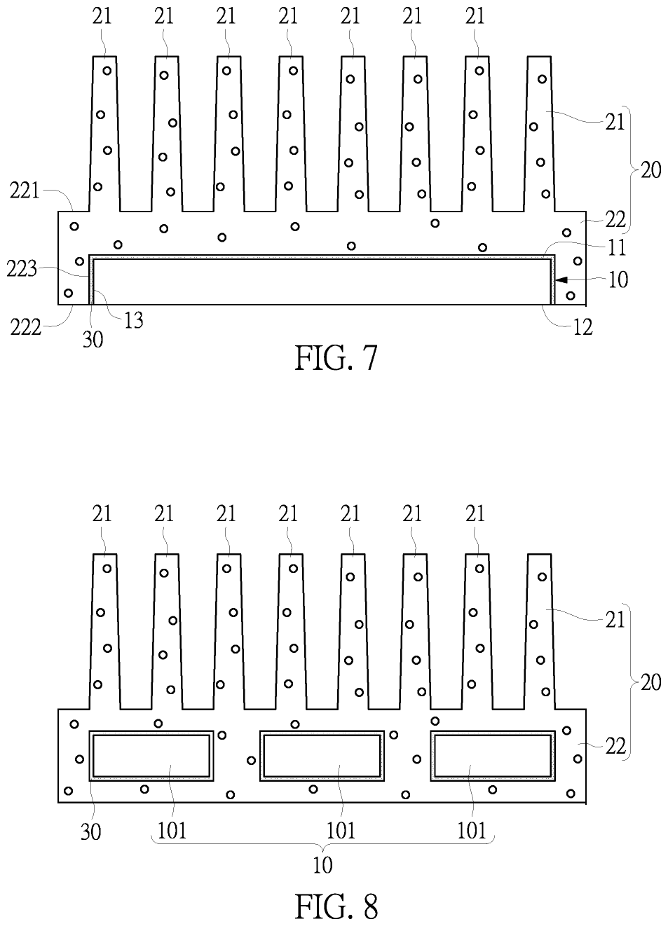

Reference is made to FIG. 7, in which a seventh embodiment of the present disclosure is shown. The present embodiment is substantially the same as the third embodiment, and differences therebetween are described as follows.

In the present embodiment, the recess 223 formed on the porous heat dissipation substrate 22 of the second heat dissipation member 20 can be jointed to the upper surface 11 and the side surface 13 by a medium 30. Further, the medium 30 can be a copper-containing solder or a thermal interface material.

### Eighth Embodiment

Reference is made to FIG. 8, in which an eighth embodiment of the present disclosure is shown. The present embodiment is substantially the same as the fourth embodiment, and differences therebetween are described as follows.

In the present embodiment, the porous heat dissipation substrate 22 of the second heat dissipation member 20 can be jointed to the first heat dissipation member 10 that is formed by the plurality of solid metals 101 by at least one medium 30. Further, the at least one medium 30 can be a copper-containing solder or a thermal interface material.

### Ninth Embodiment

In the present disclosure, the immersion-type heat dissipation structures as shown in FIG. 1A, FIG. 2, FIG. 3, and FIG. 4 can be manufactured in a manner as follows.

(a) Providing a first material. The first material can be the solid metal as shown in FIG. 1A, FIG. 2, FIG. 3 or FIG. 4.

(b) Performing a process of chemical micro-etching, that is, a surface of the first material is chemically micro-etched, so that the surface of the first material is formed as a micro-etching surface to increase an occlusion property of the surface of the first material. The chemically micro-etched first material is then placed in a metal injection mold. A cavity of the metal injection mold can have a shape corresponding to the immersion-type heat dissipation structure as shown in FIG. 1A, FIG. 2, FIG. 3, or FIG. 4.

(c) Providing a second material. The second material can be a mixture of metal powder and an adhesive. The metal powder can be copper powder, and the adhesive can be paraffin.

(d) Performing a process of metal injection molding, that is, the second material is injected into the metal injection mold by metal injection molding to form the immersion-type heat dissipation structure as shown in FIG. 1A, FIG. 2, FIG. 3, or FIG. 4.

In addition, the immersion-type heat dissipation structure as shown in FIG. 1A, FIG. 2, FIG. 3, or FIG. 4 can be post-processed according to practical requirements. The post processing can be, but is not limited to, a process of dewaxing, a process of sintering, a secondary processing (e.g., hole machining), etc.

### Beneficial Effects of the Embodiments

In conclusion, in the immersion-type heat dissipation structure and the method for manufacturing the same provided by the present disclosure, by virtue of “the immersion-type heat dissipation structure including the first heat dissipation member and the second heat dissipation member, the second heat dissipation member having a plurality of heat dissipation columns and being disposed on the first heat dissipation member, the second heat dissipation member being the porous heat dissipation member that has the porous structure, the first heat dissipation member being the solid heat dissipation member that has the solid structure, and the thermal conductivity of the first heat dissipation member being greater than the thermal conductivity of the second heat dissipation member,” the generation of vapor bubbles and the thermal transmission efficiency can be increased simultaneously, thereby increasing the overall immersion-type heat dissipation effect. In addition, by virtue of “the shortest distance between the two bottoms of any two adjacent ones of the heat dissipation columns being between 0.2 mm and 1.2 mm, the minimum diameter of the top surface of any one of the plurality of heat dissipation columns being between 0.2 mm and 1.2 mm, and the draft angle formed on the side surface of any one of the plurality of heat dissipation columns being between 1° and 5°,” the overall contact area of the second heat dissipation member with the two-phase coolant is increased by reducing the diameter of the heat dissipation column and the distance between any two adjacent ones of the heat dissipation columns, thereby further increasing the overall heat dissipation effect.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. An immersion-type heat dissipation structure, comprising:
a first heat dissipation member; and
a second heat dissipation member having a plurality of heat dissipation columns and disposed on the first heat dissipation member;
wherein the second heat dissipation member and the first heat dissipation member are at least partially in contact with each other;
wherein the second heat dissipation member is a porous heat dissipation member that has a porous structure, the first heat dissipation member is a solid heat dissipation member that has a solid structure, and a thermal conductivity of the first heat dissipation member is greater than a thermal conductivity of the second heat dissipation member;
wherein a shortest distance between two bottoms of any two adjacent ones of the heat dissipation columns is between 0.2 mm and 1.2 mm, a minimum diameter of a top surface of any one of the plurality of heat dissipation columns is between 0.2 mm and 1.2 mm, and a draft angle formed on a side surface of any one of the plurality of heat dissipation columns is between 1° and 5°.

2. The immersion-type heat dissipation structure according to claim 1, wherein the first heat dissipation member is a solid heat dissipation member that is made of at least one solid metal, and the second heat dissipation member is a porous heat dissipation member that is formed by metal injection molding and in contact with the first heat dissipation member.

3. The immersion-type heat dissipation structure according to claim 1, wherein each of the plurality of heat dissipation columns is at least one of a circular column, a square column, a diamond-shaped column, and an elliptical column.

4. The immersion-type heat dissipation structure according to claim 1, wherein the first heat dissipation member is a solid heat dissipation member that is formed by multiple solid metals, and the second heat dissipation member is a porous heat dissipation member that is formed by metal injection molding and completely covers the first heat dissipation member.

5. The immersion-type heat dissipation structure according to claim 4, wherein the multiple solid metals are made of different solid metal materials, respectively.

6. An immersion-type heat dissipation structure, comprising:
a first heat dissipation member; and
a second heat dissipation member;
wherein the second heat dissipation member and the first heat dissipation member are at least partially jointed to each other by a medium;
wherein the second heat dissipation member is a porous heat dissipation member that has a porous structure, the first heat dissipation member is a solid heat dissipation member that has a solid structure, and a thermal conductivity of the first heat dissipation member is greater than a thermal conductivity of the second heat dissipation member;
wherein a shortest distance between two bottoms of any two adjacent ones of the heat dissipation columns is between 0.2 mm and 1.2 mm, a minimum diameter of a top surface of any one of the plurality of heat dissipation columns is between 0.2 mm and 1.2 mm, and a draft angle formed on a side surface of any one of the plurality of heat dissipation columns is between 1° and 5°.

7. The immersion-type heat dissipation structure according to claim 6, wherein the medium is a copper-containing solder or a thermal interface material.

8. The immersion-type heat dissipation structure according to claim 6, wherein each of the plurality of heat dissipation columns is at least one of a circular column, a square column, a diamond-shaped column, and an elliptical column.

9. The immersion-type heat dissipation structure according to claim 6, wherein the first heat dissipation member is a solid heat dissipation member that is formed by at least one solid metal, and the second heat dissipation member is a porous heat dissipation member that is formed by metal injection molding.

10. The immersion-type heat dissipation structure according to claim 6, wherein the first heat dissipation member is a solid heat dissipation member that is formed by multiple solid metals, and the second heat dissipation member is a porous heat dissipation member that is formed by metal injection molding and completely covers the first heat dissipation member.

11. The immersion-type heat dissipation structure according to claim 10, the multiple solid metals are made of different solid metal materials, respectively.

12. A method for manufacturing an immersion-type heat dissipation structure, comprising:
providing a first material;
performing a process of chemical micro-etching on a surface of the first material, so that the surface of the first material is formed as a micro-etching surface;
placing the chemically micro-etched first material in a metal injection mold;
providing a second material; and
injecting the second material into the metal injection mold by metal injection molding to form the immersion-type heat dissipation structure as claimed in claim 1.

13. The method according to claim 12, wherein the first material is at least one solid metal, and the second material is a mixture of metal powder and an adhesive.

14. The method according to claim 12, further comprising:
performing a post processing on the immersion-type heat dissipation structure;
wherein the post processing is at least one of a process of dewaxing, a process of sintering, and a secondary processing.
